(19) United States
(12) Patent Application Publication
(10) Pub. No.: US 2006/0270827 A1
(43) Pub. Date: Nov. 30, 2006

(54) Organic light emitting materials and use thereof

(75) Inventor: Ruei-Tang Chen, Kaohsiung (TW)

Correspondence Address: LADAS & PARRY, 26 WEST 61ST STREET, NEW YORK, NY, 10023, US

(73) Assignee: ETERNAL CHEMICAL CO., LTD.

(21) Appl. No.: 11/438,107

(22) Filed: May 19, 2006

(30) Foreign Application Priority Data
May 20, 2005 (TW) 094116554

(51) Int. Cl. C09K 11/06; C08G 61/02; C08G 61/12; H05B 33/14; H01L 51/54

(52) U.S. Cl. 528/394; 428/690; 428/917; 313/504; 257/40; 257/E51.036; 257/E51.028; 528/397; 528/422; 528/423

(57) ABSTRACT

The invention provides an organic light-emitting polymer having the structure of formula (I): 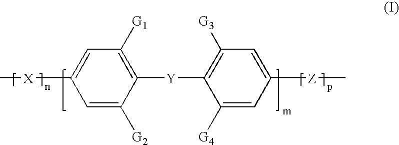 wherein each of the substituents is as defined in the specification and the attached claims. The organic light-emitting polymer can be used in the manufacture of organic light-emitting diode elements.

### FIELD OF THE INVENTION

The present invention provides an organic light-emitting material, particularly, an organic light-emitting material useful for organic light-emitting elements.

### BACKGROUND OF THE INVENTION

Light-emitting diodes have been utilized in many applications, such as traffic lights and large screens. However, most of these diodes are inorganic light-emitting diodes. The emission efficiency of a light-emitting diode based on organic materials is achieved by applying a current to the light-emitting material contained in the diode, which can be further used in the manufacture of a display. In view of the advantages of self-luminescence, short response time, low power consumption, wide viewing angle, lightweight, small thickness, high brightness, full color, and being able to show moving images, organic light-emitting diodes (OLED) satisfy the requirements associated with light, thin, short, and small portable communication products. It has been expected that OLED will become the main stream for medium to small-sized displays.

OLED was first published by KODAK Co. in 1987, which is a display element that utilizes the self-luminescence of an organic light-emitting material to achieve the displaying effect. OLED consists mainly of a pair of electrodes and an organic light-emitting layer. The organic light-emitting layer contains a light-emitting material. When an external vias voltage is applied to the display element, electrons and holes are injected to an electron-transfer layer and an hole-transfer layer, respectively, and then the injected electrons and holes travel to the organic light-emitting material and are recombined therein to generate excitons, which subsequently release energy and return to the ground state, thus producing electroluminescence. Different light-emitting materials emit different color lights.

OLED displays can be of single color, multicolor, or full color. A multicolor effect can be achieved by combining several single color light emitting regions, each of which still emits light of single color. A full-color effect can be achieved by utilizing repeating pixels emitting lights of red, green, and blue colors. The smaller size the pixels have, a higher resolution can be achieved. For the market success of display appliance, it is necessary to obtain full-color emission. The light emitting materials used in full-color organic light-emitting elements require blue color light emitting material, green color light emitting material, and red color light emitting material. Moreover, by incorporating a dopant into the emissive layer of the organic light emitting elements, the energy can be transferred from the host to the dopant, such that the emitted light color and emission efficiency of the host can be changed. In this energy-transfer way, the original high-energy light color of the host will shift to low-energy light color. Moreover, if the emission efficiency of a host is higher, it will be easier that the energy is transferred to a dopant and to obtain red, blue, and green colors.

J. Am. Chem. Soc. 2003, 125, 636-637 discloses the preparation of a polymer by bonding a low-energy red light-emitting structure to a high-energy blue light-emitting structure, such that the light emitted by an OLED element produced from the resultant polymer shifts from blue to red. J. Am. Chem. Soc. 2004, 126, 7718-7727 discloses mixing small red color light emitting molecules with blue color light emitting polymers at different ratios, such that the light emitted by an OLED element produced from the resultant mixture shifts from blue to red.

The above-published organic light-emitting materials only emit light up to the blue region. However, the full-color light emitting elements with a color display by transferring the blue light energy to a dopant no longer meet current demands. To obtain higher quality, full-color organic light emitting elements, there is a need for an organic light emitting material that emits higher energy light (such as violet or ultraviolet light) than blue color light, such that when the organic light emitting material is used as a host material, the energy can be more easily transferred to a dopant and a better full-color effect can be achieved.

### SUMMARY OF THE INVENTION

In general, a basic method for changing the wavelength of the light emitted by a polymer is to change the band gap of the material itself, which is associated with the effective conjugate length of the polymer material. A longer conjugate length will result in a narrower band gap, and the emitted light wavelength will shift to a longer wavelength. On the contrary, the emitted light wavelength will shift to a shorter wavelength if the conjugate length is shortened.

The present invention provides a novel organic light emitting material, which not only can emit high-energy ultraviolet light by itself, but also emit various lights by incorporating different emissive dopants. Namely, by changing the species of the light-emitting dopant, the energy of the host can be transferred to the dopant, so as to change the light color of the host and obtain the primary red, blue and green colors more easily.

The organic light-emitting material according to the present invention comprises a polymer having a structure of formula (I): 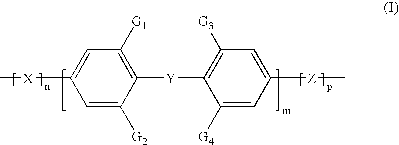
wherein:
n and m are independently an integer greater than 1;
p is 0 or an integer greater than 1;
X and Z are independently a substituted or unsubstituted C₄-C₆₀ aromatic unit or aliphatic unit;
Y is a substituted or unsubstituted C₂-C₄₀ aliphatic unit; and
G₁, G₂, G₃ and G₄ are each independently a substituted or unsubstituted C₁-C₁₂ aliphatic group.

The material of the invention can be used in the light-emitting layer of an organic light-emitting diode and emits violet or ultraviolet light. The material of the invention can also obtain various light colors by incorporating a light-emitting dopant and exhibits good emission efficiency.

### BRIEF DESCRIPTION OF THE DRAWING

FIG. 1 represents the electroluminescent (EL) spectrum measured for an organic light-emitting element according to the present invention.

### DETAILED DESCRIPTION OF THE INVENTION

The light-emitting material according to the present invention is characterized by a conjugated structure present in the main polymer chain and an emissive unit contained in part of the conjugated polymer. Since the emissive units are separated by a non-conjugated moiety, the conjugate length of the emissive units can be shortened such that the emitted light wavelength shifts to the ultraviolet region with a shorter wavelength.

According to a preferred embodiment of the present invention, in the polymer of formula (I), n and m are each independently an integer from 5 to 600; p is 0 or an integer from 1 to 300; X and Z are each independently a substituted or unsubstituted C₆-C₄₀ aromatic unit or aliphatic unit; Y is a substituted or unsubstituted C₃-C₂₀ aliphatic unit; and G₁, G₂, G₃ and G₄ are each independently a substituted or unsubstituted C₁-C₆ aliphatic group.

According to another preferred embodiment of the present invention, in the above formula (I), X and Z are each independently a substituted or unsubstituted C₆-C₄₀ aromatic unit, including, but not limited to, the following aromatic units: 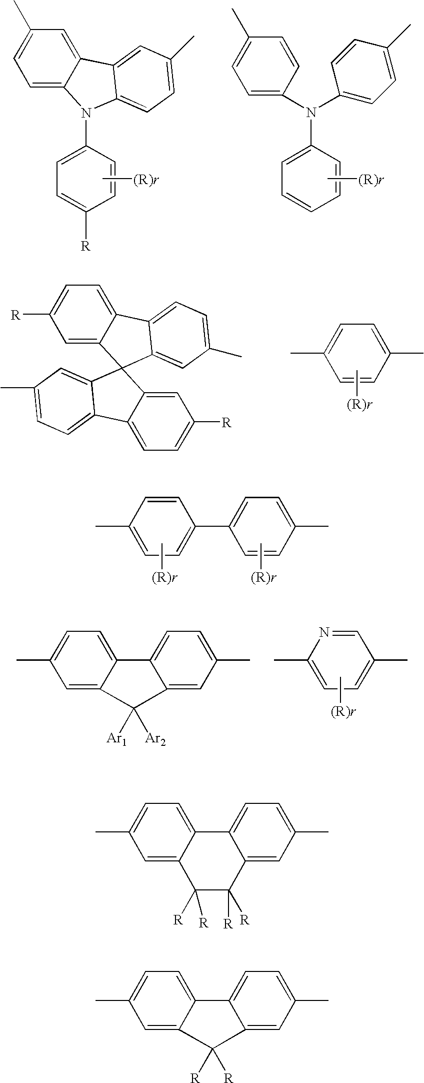
wherein each R independently represents a C₁-C₁₆-alkyl or C₁-C₁₆-alkoxy; r is 0, 1, 2, or 3; and Ar₁ and Ar₂ are each independently a substituted or unsubstituted C₆-C₁₀ aromatic group, preferably a substituted or unsubstituted phenyl. X preferably is: 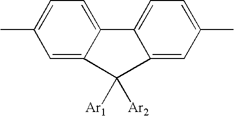
wherein Ar₁ and Ar₂ are as defined above.

More preferably, X is

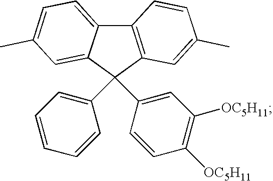

Z preferably is: 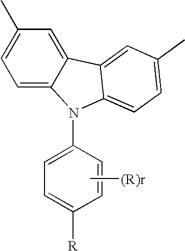
wherein R and r are as defined above.

More preferably, Z is:

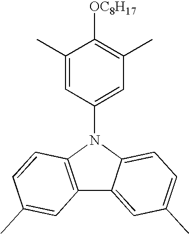

According to a preferred embodiment of the present invention, in the above formula (I), Y is a substituted or unsubstituted C₃-C₂₀ aliphatic unit. More preferably, Y is a substituted or unsubstituted C₄-C₁₂ hydrocarbon chain or alkanediyl bisoxy. Most preferably, Y is butanediyl bisoxy.

According to a preferred embodiment of the present invention, in the above formula (I), G₁, G₂, G₃ and G₄ are each independently a substituted or unsubstituted C₁-C₆ aliphatic group; more preferably, a substituted or unsubstituted methyl, ethyl, propyl, butyl, methoxy, ethoxy, or propoxy; most preferably, methyl.

According to a preferred embodiment of the present invention, in the above formula (I), n and m are each independently an integer from 5 to 600 and p is 0 or an integer from 1 to 300. More preferably, n and m are each independently an integer from 10 to 300 and p is an integer from 5 to 150. The average molecular weight of the polymer of formula (I) according to the present invention is between 20,000 and 2,000,000, preferably between 50,000 and 1,200,000.

The organic light-emitting material of the present invention can be used in an organic light-emitting diode element as a light-emitting layer material and exhibits good emission efficiency. The polymer of the present invention can be incorporated into an organic light-emitting diode (OLED) element as a light-emitting layer material or a part of the light-emitting layer material by any conventional method known in the art. In other words, the material of the present invention can be blended together with other materials in various proportions prior to being coated onto an element as a light-emitting layer material. When the emissive layer is doped with an emissive dopant by, for example, a doping technique, with the use of the organic light-emitting polymer of formula (I) as either the energy host or the dopant guest, the emission efficiency can be enhanced and the light color can be tuned.

The present invention will be further illustrated by the following examples, which are not to be construed as limiting the protection scope of the invention.

### Preparation of Organic Light-Emitting Materials

Preparation of Monomers

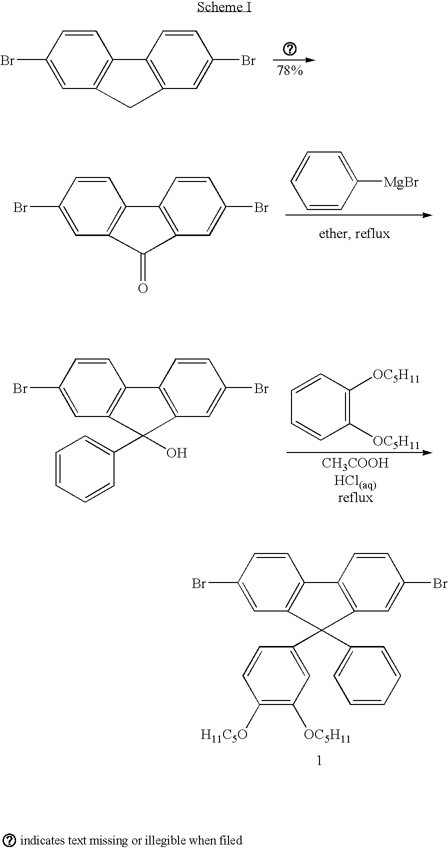

According to Scheme I, 2,7-dibromofluorene in acetic acid was oxidized with the oxidant, chromiumoxide, such that the 9 position of the fluorene was oxidized to a ketone group, thereby allowing the carbon on position 9 to partially carry positive charge. Thereafter, the resultant compound was dissolved in ether followed by the addition of an aryl Grignard reagent. The reaction was refluxed to attach the aryl group to position 9. Thereafter, the resultant compound was dissolved in ether, refluxed, and subjected to Friedel-Crafts reaction in the presence of 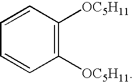
In this way, a second aryl can be attached to position 9 so as to obtain Product 1 (i.e., 9,9-diaryl-substituted fluorene intermediate) as shown in Scheme I.

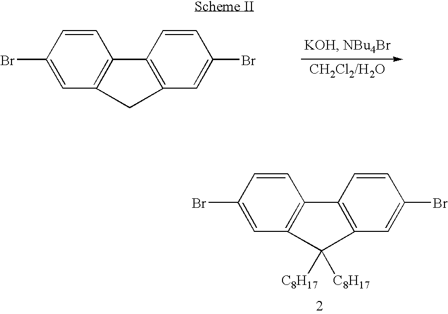

According to Scheme II, 2,7-dibromofluorene was dissolved in dichloromethane followed by the addition of a tetrabutyl ammonium salt and 2M aqueous potassium hydroxide solution. The reaction was heated and Product 2 as shown in Scheme II was obtained.

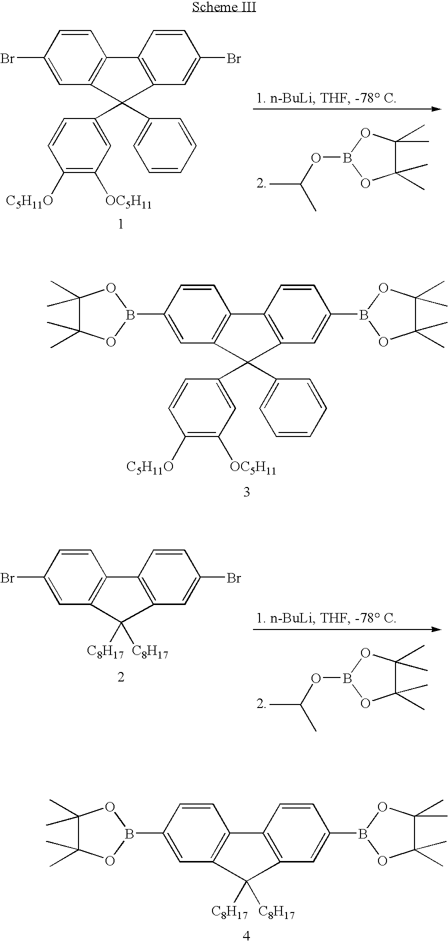

According to Scheme III, Product 1 (or Product 2) was dissolved in THF and reacted with n-butyl lithium (n-BuLi) and a borate at 78° C. to replace the bromine on the Products and to attach the borate to the Products. Product 3 and Product 4 as shown in Scheme III were obtained, respectively.

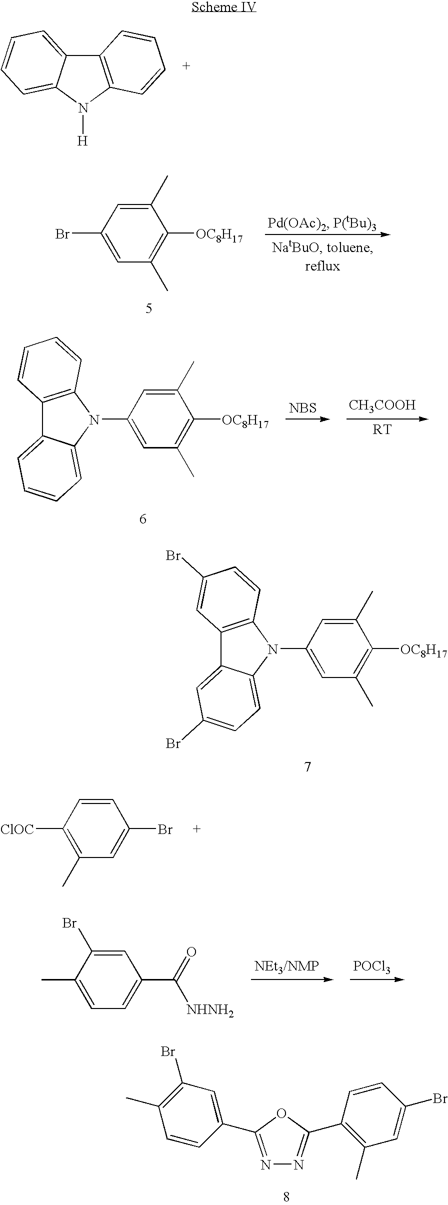

According to Scheme IV, carbazole and Compound 5 were dissolved in toluene and refluxed in the presence of Pd(OAc)₂, P(tBu)₃ and NatBuO. Under the catalysis of Pd, Product 6 was obtained, Thereafter, a bromination reaction was conducted with N-bromosuccinimide (NBS) to obtain Product 7 as shown in Scheme IV.

According to Scheme IV, 2-Methyl-4-bromobenzoyl chloride was reacted with 3-bromo-4-methyl benzoylhydrazine under basic conditions, and then the dehydration and cyclization with POCl₃ were conducted to obtain Monomer B.

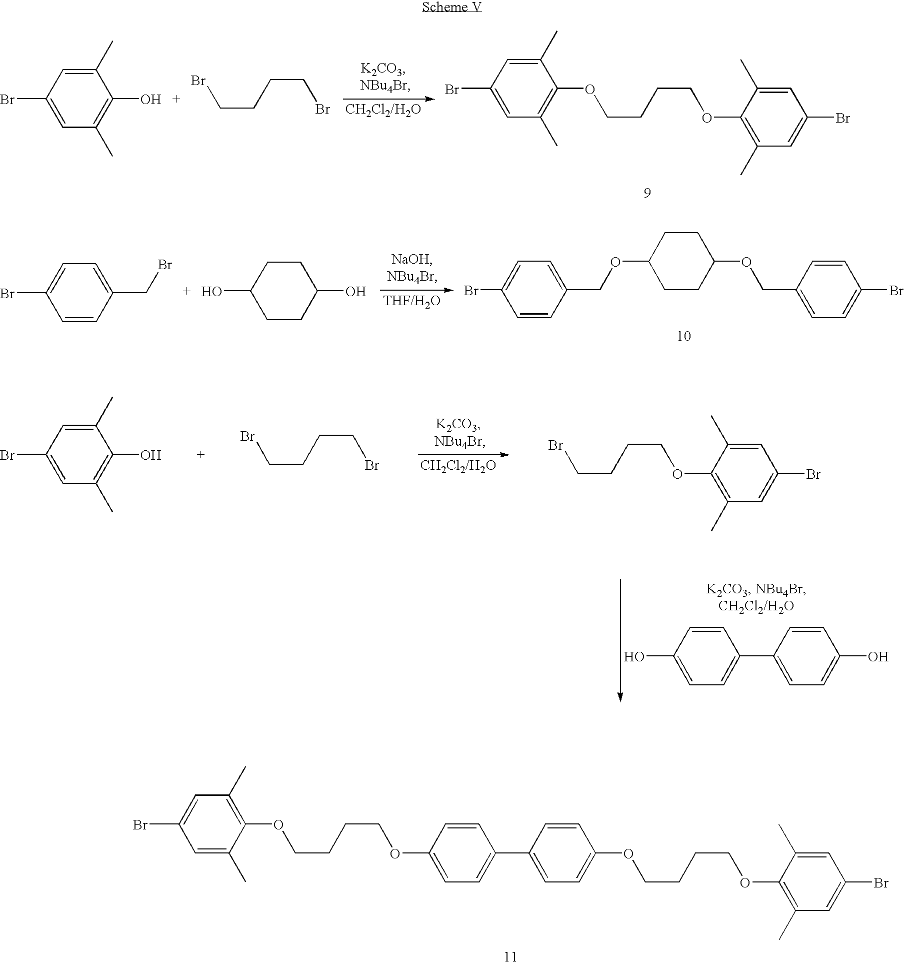

According to Scheme V, in the presence of a tetrabutyl ammonium salt, 4-bromo-2, 6-dimethylphenol was deprotonated by potassium carbonate and then reacted with 1, 4-dibromobutane to obtain Product 9 as shown in Scheme V. Products 10 and 11 can be obtained under similar conditions.
Synthesis of Organic Light-emitting Materials

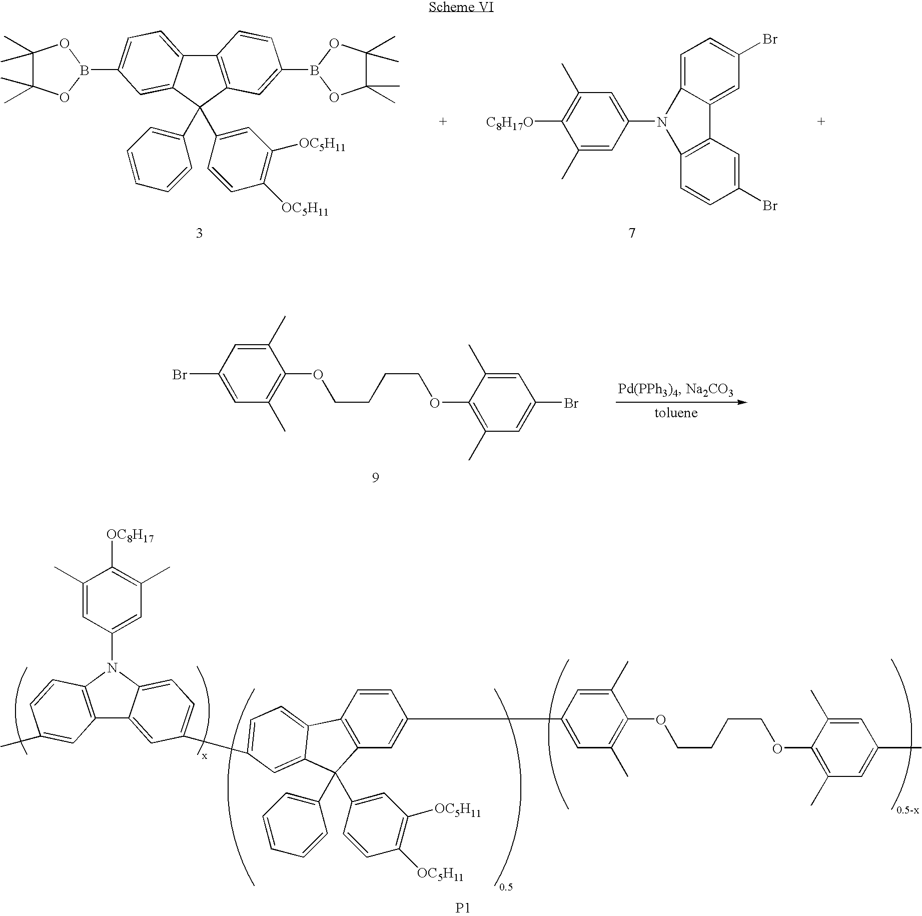

According to Scheme VI, the three monomers produced according to Scheme I to V were together dissolved in toluene to form a reaction solution. The reaction solution was subjected to a Suzuki coupling reaction in the presence of Pd(PPh₃)₄ and Na₂CO₃ to obtain Polymer P1 as shown in Scheme VI.

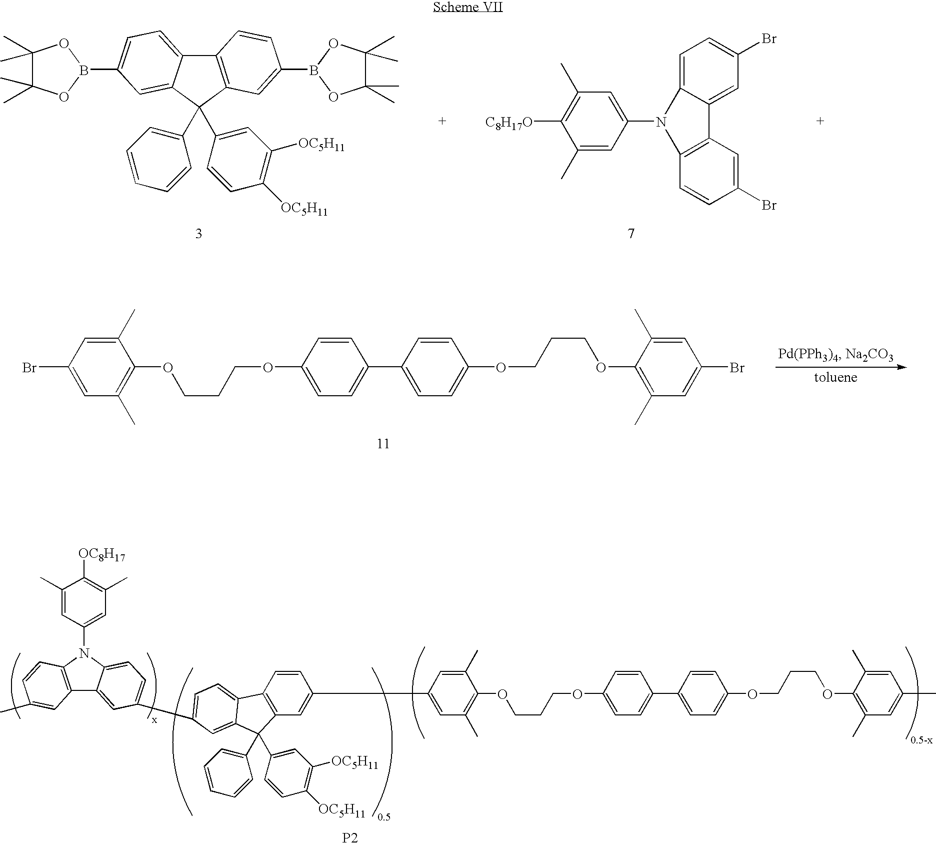

According to Scheme VII, the three monomers produced according to Scheme I to V were together dissolved in toluene to form a reaction solution. The reaction solution was subjected to a Suzuki coupling reaction in the presence of Pd(PPh₃)₄ and Na₂CO₃ to obtain Polymer P2 as shown in Scheme VII.

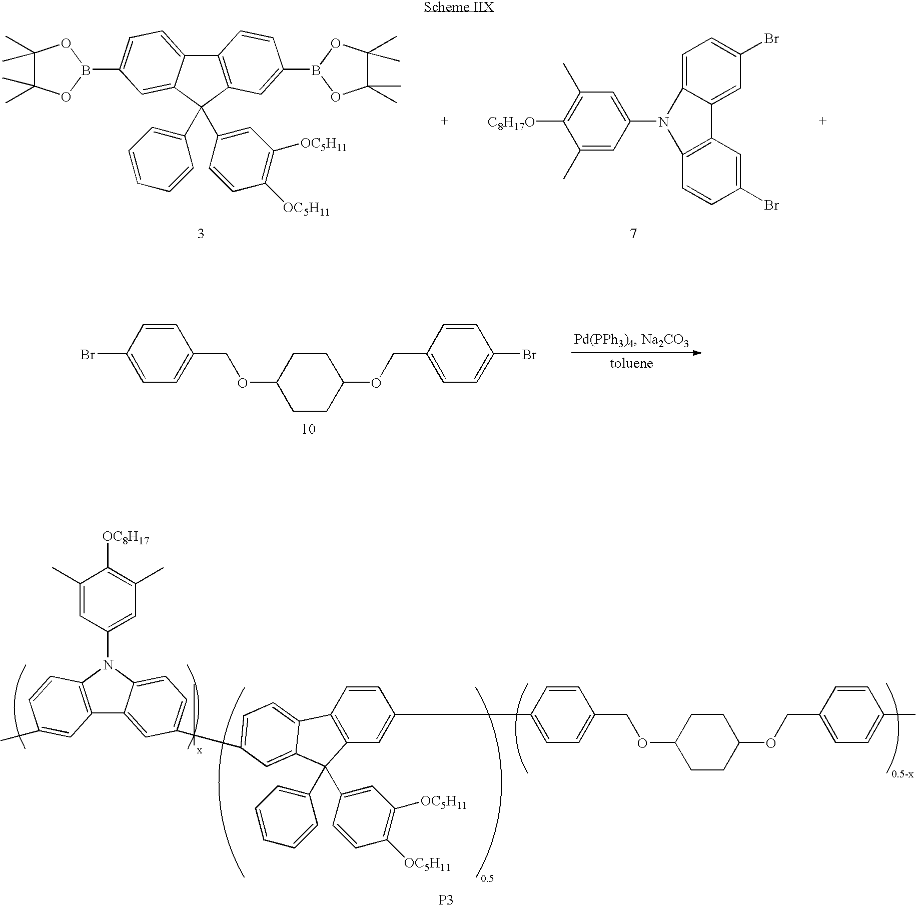

According to Scheme IIX, the three monomers produced according to Scheme I to V were together dissolved in toluene to form a reaction solution. The reaction solution was subjected to a Suzuki coupling reaction in the presence of Pd(PPh₃)₄ and Na₂CO₃ to obtain Polymer P3 as shown in Scheme IIX,

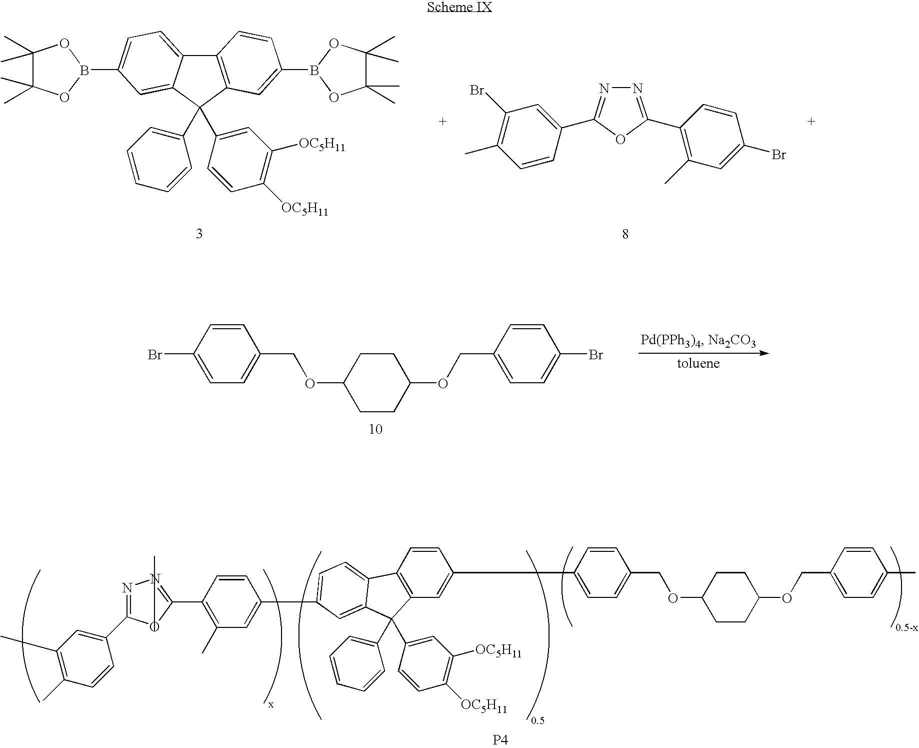

According to Scheme IX, the three monomers produced according to Scheme I to V were together dissolved in toluene to form a reaction solution. The reaction solution was subjected to a Suzuki coupling reaction in the presence of Pd(PPh₃)₄ and Na₂CO₃ to obtain Polymer P4 as shown in Scheme IX.

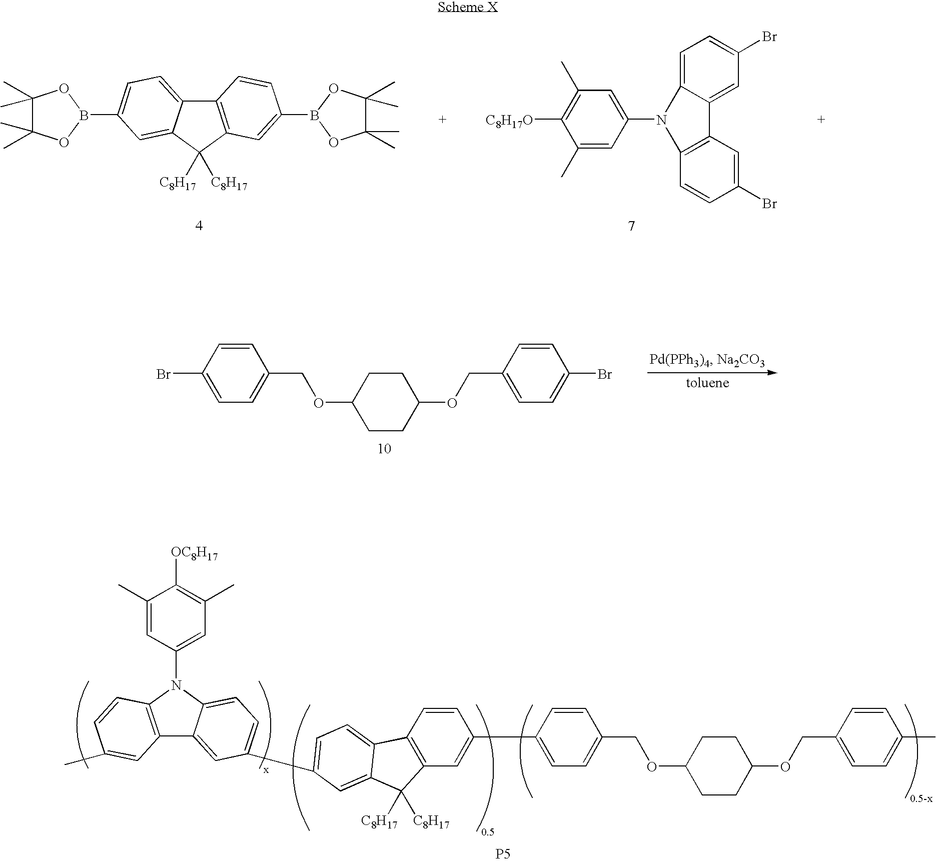

According to Scheme X, the three monomers produced according to Scheme I to V were together dissolved in toluene to form a reaction solution. The reaction solution was subjected to a Suzuki coupling reaction in the presence of Pd(PPh₃)₄ and Na₂CO₃ to obtain Polymer P5 as shown in Scheme X.

Physical Properties of Organic Light-emitting Polymers

The above-obtained Polymers 1 to 5 were tested for their physical properties. The results are shown in the following table:

| | | | | Maximum | Maximum |
|---|---|---|---|---|---|
| | | | | Absorption | Emission |
| | | | | Wavelength | Wavelength |
| Polymer | Mw | Mn | Mw/Mn | (nm) | (nm) |
| P1 | 71217 | 36720 | 1.939 | 328 | 395 |
| P2 | 43953 | 23164 | 1.90 | 338 | 396 |
| P3 | 30992 | 17800 | 1.74 | 334 | 398 |
| P4 | 25590 | 14285 | 1.79 | 335 | 398 |
| P5 | 24089 | 13665 | 1.76 | 332 | 394 |

### Organic Light-emitting Element

Preparation of Organic Light-emitting Element

The organic light-emitting Polymer 1 was dissolved in toluene at a concentration of from 1% to 3%, and then spin coated at 500 rpm to 3000 rpm to the surface of indium tin oxide (ITO) glass. The resultant film was heated in a vacuum oven at 100° C. for 30 minutes. An Al electrode was plated onto the film such that an organic light-emitting element was produced.

Light-emitting Properties of Organic Light-emitting Element

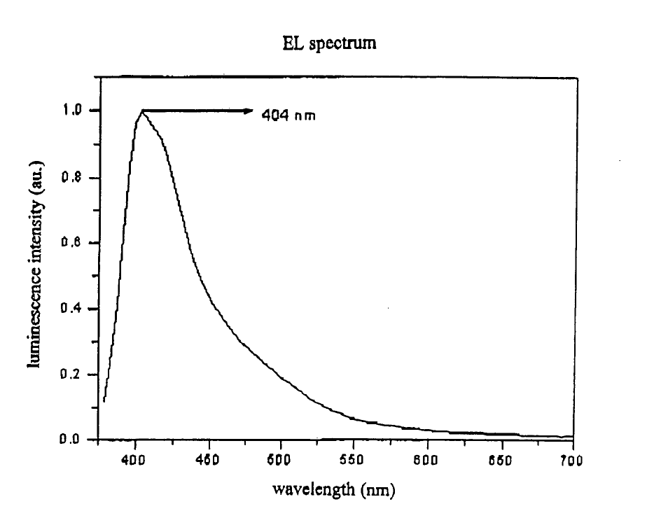

The above-produced organic light-emitting element was subjected to a driving voltage of 3 Volts to 20 Volts. The electroluminescent spectrum for the element using Kodak's PR650 spectrophotometer was obtained as shown in FIG. 1. According to FIG. 1, the emissive wavelength at the maximum emission intensity of the film formed from the organic light-emitting material of the present invention is 404 nm, within the ultraviolet region, which shows that the partial conjugate portion contained in the main chain of the inventive organic light-emitting polymer does allow the polymer to emit a light with a shorter wavelength.

What is claimed is:

1. An organic light-emitting polymer having a structure of formula (I): 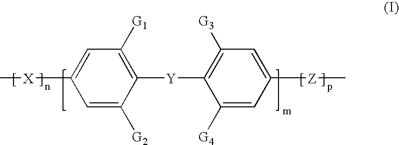
wherein:
n and m are independently an integer greater than 1;
p is 0 or an integer greater than 1;
X and Z are independently a substituted or unsubstituted C₄-C₆₀ aromatic unit or aliphatic unit;
Y is a substituted or unsubstituted C₂-C₄₀ aliphatic unit; and
G₁, G₂, G₃ and G₄ are each independently a substituted or unsubstituted C₁-C₁₂ aliphatic group.

2. The organic light-emitting polymer according to claim 1, wherein n and m are each independently an integer from 5 to 600 and p is 0 or an integer from 1 to 300.

3. The organic light-emitting polymer according to claim 1, wherein X and Z are each independently a substituted or unsubstituted C₆-C₄₀ aromatic unit or aliphatic unit.

4. The organic light-emitting polymer according to claim 3, wherein X and Z are each independently selected from the group of the following: 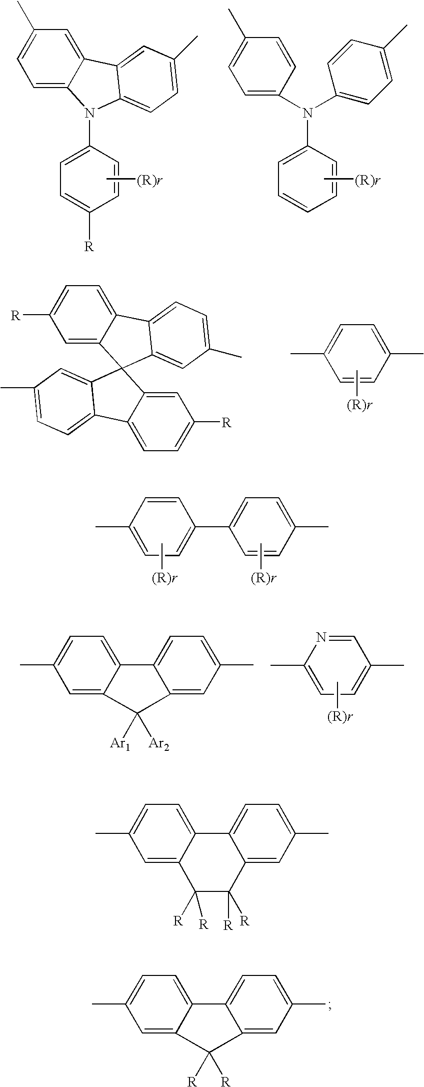
wherein each R independently represents a C₁-C₁₆-alkyl or C₁-C₁₆-alkoxy; r is 0, 1, 2, or 3; and Ar₁ and Ar₂ are each independently a substituted or unsubstituted C₆-C₁₀ aromatic group.

5. The organic light-emitting polymer according to claim 1, wherein Y is a substituted or unsubstituted C₃-C₂₀ aliphatic unit.

6. The organic light-emitting polymer according to claim 5, wherein Y is a substituted or unsubstituted C₄-C₁₂ hydrocarbon chain or C₄-C₁₂ alkanediyl bisoxy.

7. The organic light-emitting polymer according to claim 1, wherein G₁, G₂, G₃ and G₄ are each independently a substituted or unsubstituted C₁-C₆ aliphatic group.

8. The organic light-emitting polymer according to claim 7, wherein G₁, G₂, G₃ and G₄ are each independently a substituted or unsubstituted methyl, ethyl, propyl, butyl, methoxy, ethoxy, or propoxy.

9. The organic light-emitting polymer according to claim 1, having an average molecular weight of between 20,000 and 2,000,000.

10. The organic light-emitting polymer according to claim 9, having an average molecular weight of between 50,000 and 1,200,000.

11. An organic light-emitting element with an organic light-emitting layer comprising the organic light-emitting polymer according to claim 1.
